(19) United States
(12) Patent Application Publication
(10) Pub. No.: US 2008/0150491 A1
(43) Pub. Date: Jun. 26, 2008

(54) Method Of Estimating The State-Of-Charge And Of The Use Time Left Of A Rechageable Battery, And Apparatus For Executing Such A Method

(75) Inventors: Hendrik Johannes Bergveld, Eindhoven (NL); Valer Pop, Enschede (NL); Petrus Henricus Laurentius Notten, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/598,038

(22) PCT Filed: Feb. 23, 2005
(86) PCT No.: PCT/IB2005/050658

§ 371 Date: Aug. 16, 2006

(30) Foreign Application Priority Data
Feb. 25, 2004 (EP) 04100743.6

(51) Int. Cl. G01R 31/36; H02J 7/00; H01M 10/44

(52) U.S. Cl. 320/139; 320/149

(57) ABSTRACT

Disclosed is a method of estimating the state-of-charge of a rechargeable battery, taking into account the factors battery spread and ageing. The method comprises the steps of: determining the starting state-of-charge of the battery by measuring the voltage across the battery and converting this measured value into a state-of-charge value; charging the battery; integrating the charge current and determining the accumulated charge during charging of the battery and adding said value to the starting state-of-charge. Also disclosed is a method for determining the use time left of a rechargeable battery.

The invention relates to a method of estimating the state-of-charge of a rechargeable battery.

More in particular the invention relates to a method of estimating the state-of-charge of a Li-ion battery, comprising the steps of measuring the voltage across the battery during a first measurement and converting this measured value into the state-of-charge (SoCₛ), subsequently charging the battery, measuring the voltage across the battery during a second measurement and converting this measured value to a measured state-of-charge value (SoCₑ), determining the accumulated charge during charging by integration of the charge current, subtracting the measured state of charge (SoCₛ) in the first measurement from the state-of-charge (SoCₑ) in the second measurement and updating the value of the maximum capacity of the battery (Capₘₐₓ) by relating the charge withdrawn from the battery with the result of the subtraction (SOCₑ-SOCₛ). Such a method is described in U.S. Pat. No. 6,515,453.

Often there is a wish to have access to the value of the state-of-charge not only during equilibrium of the battery but also at other times, for instance when a charge cycle is not completed because the user starts using the device powered by the battery before charging is completed and hence the equilibrium of the battery is not reached.

This aim is reached by such a method wherein at least the second measurement is executed during charging.

It has appeared that the during charging in the C-V-regime the charge current slowly decreases and that it reaches such a low value that the battery can be regarded to be in its equilibrium or to be very close to it. When the second measurement is executed with such a small current, such a measurement may be used to update the value of the maximum capacity of the battery, leading to greater accuracy of the state-of-charge.

According to a first preferred embodiment, the second measurement is executed when the current has a value at which the battery can be regarded to be in equilibrium. This leads to an even higher accuracy.

It is common for Li-ion-batteries to be charged according to the according to the CC-CV-regime. Then it is advantageous that the second measurement takes place in the CV-regime, preferably at the end thereof as then low values of currents are reached.

Often the charge circuit makes use of a pulsed or chopped current. Then it is advantageous to make use of low pass filtering to obtain measurement values of the current.

The method according to the invention makes use of the relation between state-of-charge and the Elektro-Motive Force of a battery. This relation is dependant on the temperature. Therefore it is advantageous that both measurements of the voltage of the battery take place with substantially the same temperature.

To allow an assessment of the state-of-charge ate times when the battery is charged or discharged a preferred embodiment provides a method comprising the steps of measuring the voltage of the battery in equilibrium, converting the measured voltage to a relative state-of-charge, integrating of the current to an accumulated charge, dividing the accumulated charge by the maximal capacity of the battery and adding the accumulated relative charge to the a relative state-of-charge obtained earlier in the equilibrium state of the battery.

Herein the value of the current may be negative to allow not only for charging but also for discharging.

The rather accurate determination of the state-of-charge of a battery can be used to calculate an estimation of the remaining time of use of the battery.

Another factor which plays a role in the determination of the remaining time of use is the overpotential, that is the difference between the voltage in the equilibrium state and the state wherein current is charged to or withdrawn from the battery. Therefore it is advantageous to take account of this factor during the modeling of the state-of-charge, to allow measurements to be made during charging or discharging of the battery.

Hence a preferred embodiment of the invention provides the feature that in the calculation of the remaining time of use an estimation of the overpotential is used.

To allow a more accurate modeling it is preferred when that the model used by determination of the overpotential is regularly updated.

An efficient way for this updating comprises the steps of determining the state of charge of the battery, charging the battery, measuring the battery voltage at a moment during charging, determining the state-of-charge of the battery at the moment of the measurement by integration of the charge current and adding the result to the initial value of the state-of-charge determining the value of the EMF from the state-of-charge:

determining the overpotential by subtracting the determined value of the EMF from the measured voltage, estimating the overpotential through a model wherein the same values for state-of-charge, current and temperature are used and adapting the model by comparison with the determined overpotential.

As the overpotential is dependant on several variables it is advantageous to repeat the method with another value of any of the following parameters: the state-of-charge, the charge current or the temperature.

Another preferred embodiment provides the feature that the method is repeated more than once and that the parameters used in the design are adaptively updated with each measurement. A reason for this iterative process resides in the fact that the state-of-charge is dependent on the overpotential, but that the overpotential itself is also dependant on the state-of-charge.

The invention relates also to an apparatus for executing the methods described above; this apparatus can be incorporated into a battery but also in a charger.

More in particular the invention relates to an apparatus, comprising measuring means for measuring the voltage across a rechargeable battery, storage means for storing a relation between the voltage across the battery and the state-of-charge of the battery and calculating means for converting this measured value into a state-of-charge value (SoCₛ) by using a relation between the voltage across the battery and the state-of-charge, wherein the calculating means are adapted to subtract the results of two consequtive measurements and to update the value of the maximum capacity of the battery (Capₘₐₓ) by relating the charge withdrawn from the battery with the result of the subtraction (SoCₑ-SoCₛ), which apparatus is characterized in that the apparatus is adapted to execute the second measurement during charging.

The main feature of the method is that SoC estimation is performed by means of voltage measurement when the battery is in the so-called equilibrium state and by means of current measurement when the battery is in a non-equilibrium state. In the case of equilibrium no or only a small external current flows and the battery voltage has fully relaxed from previous charges or discharges. The measured battery voltage is practically equal to the Electro-Motive Force (EMF) of the battery in equilibrium conditions. Therefore, a stored curve, plotting the EMF versus the SoC expressed in percentage of the full scale, is used to translate the measured battery voltage into a battery SoC in percentage of the full scale. When the battery is in a non-equilibrium state, the battery is either charged or discharged and the charge withdrawn from or supplied to the battery is calculated by means of current integration. This charge is subtracted from or added to an SoC value calculated earlier. It is important to note that in equilibrium mode the SoC is expressed in a percentage of the maximum capacity Capₘₐₓ, i.e. on a relative scale. In non-equilibrium however, the current integration yields an absolute value of charge and this value needs to be translated to the relative scale using the Capₘₐₓ parameter.

In addition to estimating the SoC, which is a measure of the amount of charge still present inside the battery, the method also predicts the remaining time of use of the application under predefined conditions. This is done by estimating the time it will take before the battery voltage will drop below the so-called End-of-Discharge voltage V_{EoD}. This is the minimum voltage below which the application will no longer function. In order to estimate this time, the course of the battery voltage is predicted for a chosen load condition based on the present value of the SoC, the stored EMF curve and the so-called overpotential function. When a battery is discharged, its voltage can be found by subtracting the overpotential from the EMF value. The overpotential depends on several factors, including the SoC, current, temperature and time, but also on factors such as the ohmic series resistance of the electrodes.

The main problem of the existing invention described in U.S. Pat. No. 6,515,453 is that no method is presented to deal with battery spread and ageing. Spread leads to variations in behaviour of batteries of the same batch. Ageing of a battery will cause the parameters determining the battery behaviour to change. When no precautions are taken in the SoC algorithm, i.e. parameters in the algorithm describing battery behaviour are kept constant, the estimations of the SoC will become less and less accurate, the more the actual battery behaviour changes due to ageing. Therefore, it is essential to add some kind of adaptivity to the algorithm.

In earlier research it was found that the shape of the EMF curve, when plotted on a relative or percentage scale, hardly changes when the battery ages. The EMF curve does depend on temperature to some extend, but the temperature dependence is known in the form of a physical equation in which temperature occurs as variable. When this physical equation is used to store the EMF curve, the temperature-dependence of the EMF curve can be dealt with. This latter fact was not considered in U.S. Pat. No. 6,420,851, but is considered in this invention.

The fact that the EMF curve shape hardly depends on battery ageing is used in U.S. Pat. No. 6,515,453 as an advantage. Because the shape of the EMF does not change during ageing, the SoC determined from the EMF curve is used to calibrate the system. However, it is commonly known that the maximum battery capacity Capₘₐₓ decreases over time (named q_{maz} in U.S. Pat. No. 6,515,453). This is not dealt with in U.S. Pat. No. 6,515,453. This has some serious consequences, as the translation of integrated charge to a percentage scale in non-equilibrium states is performed based on this Capₘₐₓ parameter. Moreover, as will be shown later, the remaining time of use indication based on the overpotential description also uses the Capₘₐₓ parameter.

A simple method to update Capₘₐₓ is based on relating the integrated charge withdrawn from a battery in non-equilibrium (discharge) mode to the difference in SoC (in %) in equilibrium mode directly before and after the non-equilibrium mode. Therefore, it is necessary to have a succession of states in the algorithm of equilibrium state ->discharge state ->transitional state ->equilibrium state.

A disadvantage of this set-up is that in practical use of a portable device with the implemented SoC algorithm the transitional state might take a long time. Therefore, it is plausible that very often the second equilibrium state is not reached and SOC_{E} cannot be determined, because the user will switch on the device again leading to a shift back to discharge state. It is an advantage to perform the Capₘₐₓ update under conditions that are more or less under control. This is the case during charging: the charge current is constant, as opposed to the discharge current which may vary a lot depending on the application, and the temperature can be considered constant, because the battery is placed in a charger at a fixed position. During discharging the temperature may be variable, especially when the user is moving around. Although in the text below FIG. 6.25 in thesis and book it is mentioned that ‘a similar updating mechanism can be implemented during charging’, this is not further explained. Part of this Invention Disclosure describes how to implement this, including some new insights.

In addition to a decrease in Capₘₐₓ occurring when the battery ages, the overpotential development of the battery will also change over time. A simple reason for this is the fact that ohmic series resistance of the electrodes will increase over time. Moreover, contact resistance between the battery and portable device terminals will vary over time as well. In addition to variations in ohmic resistance, the other contributions to the overpotential related to chemical behaviour of the battery will also change during the lifetime of the battery. When this change in overpotential behaviour is not taken into account in the SoC algorithm, the ‘remaining time of use’ estimation, that is based on the overpotential behaviour description, will have less and less accuracy when the battery ages. This Invention Disclosure describes a method of updating the overpotential parameters during charging of the battery.

In summary, a proper updating algorithm for Capₘₐₓ and the overpotential function ensures sustained accuracy of the SoC estimation while the battery ages. This Invention Disclosure describes these updating algorithms to be applied in the SoC algorithm of U.S. Pat. No. 6,515,453. In addition to a description of the overpotential behaviour of the battery, which has already been introduced in U.S. Pat. No. 6,515,453, this Invention Disclosure also introduces a physical equation for implementing the EMF curve, including temperature as a parameter. In fact, this means that a physical model of the battery is used, based on which the battery voltage course for various conditions can be calculated. Using a physical battery model to predict SoC has been disclosed in U.S. Pat. No. 6,016,047.

The proposed updating mechanisms for both Capₘₐₓ and the overpotential function take advantage of the fact that the update is performed during charging. As a main advantage, the charger can force the battery to proceed through a number of stages necessary to update parameter values without user intervention, because the user will place the battery in the charger and leave it there for some time (especially during overnight charging). Moreover, the external battery conditions during charging of the battery, including charge current and battery temperature, are constant. This makes any update mechanism easier to implement, but the methods described below are not restricted to any specific current or temperature value and can therefore still operate under varying conditions. The basic ideas of the updating mechanisms for Capₘₐₓ and overpotential functions will be explained below, including advantages.

At some moment in time, not necessarily when the battery is empty, the user will place the battery in the charger. Upon connection to the charger, the charger should first check whether the battery is in equilibrium before the battery is charged. At the moment the battery is in equilibrium, the SoC (in %) is determined based on the EMF method and charging is started. The user will not intervene with this process in practice. During charging the charge current is integrated and the accumulated charge Qin, starting at zero when the charging current is first applied, is determined.

As a possible alternative, when the battery is not in equilibrium when it is connected to the charger, the latest SoC value can also be used as a starting value to prevent a long waiting time before actual charging can start. It should be noted that the algorithm of U.S. Pat. No. 6,515,453 uses the equilibrium mode to calibrate the SoC estimation. SoC estimations obtained during non-equilibrium modes will slowly drift away from the real value due to the integration over time of current measurement errors. However, it is very likely to assume that the algorithm will reside in equilibrium mode at least once every 24 hours, as the phone will be in standby mode only or even off during the night. Therefore, the accumulation of errors will only take place over a limited period of less than 24 hours anyway. This means that, although waiting for the SoC value in equilibrium mode is preferred, one could also use the last available SoC estimation from non-equilibrium mode.

Every rechargeable Li-ion battery is charged using the so-called CC-CV regime, where the battery is first charged with a constant current (CC) and subsequently with a constant voltage (CV). In the CC region the voltage slowly rises until it reaches the value specified by the CV region. At this moment the CV region is entered, during which the battery voltage is actively forced to remain at the CV level and the charge current will drop until it falls below a certain small value Iₘᵢₙ. Note that in some cases the CC current has been implemented using current pulses of which the average value equals the desired Constant Current. This is no restriction for the presented solution, although in a practical implementation this could mean that the battery current and voltage measurements should be low-pass filtered before being fed to the algorithm.

An important feature of this method of charging, which is applied in most commercially available Li-ion chargers (some chargers end charging in CV mode after a fixed time), is the fact that by definition the battery voltage has fully relaxed when the charge current drops below the current level Iₘᵢₙ. Moreover, because of the very small value of this current in practice, the battery voltage at that moment is practically equal to the EMF value. That means that by definition, each time the charger reaches the stage of Iₘᵢₙ at the end of charging, the SoC algorithm resides in equilibrium state. Therefore, the necessary condition that before and after application of the charge current the battery needs to be in a state of equilibrium is achieved each time the battery is fully charged. Hence, as an advantage of the newly proposed algorithm, updating of Capₘₐₓ is possible many more times than when this method is applied in discharge mode. The new value of Capₘₐₓ can now be found from:

$${Cap}_{max} = \frac{100}{{SoC}_{end of charging} [ \% ] - {SoC}_{beginning of charging} [ \% ]} \cdot {Q}_{i n} [ C ]$$

where the SoC at the end of charging is obviously higher than the SoC at the beginning of charging. Both SoC values are determined based on voltage measurement and the stored EMF curve (unless the starting value of SoC is taken from a non-equilibrium value, as described above). Qᵢₙ is determined by current measurement and integration during the charging process and starts at zero at the beginning of charging. Note that the method is independent of the SoC valid when the battery is connected to the charger. An embodiment will be sketched in the next section.

The main problem with overpotentials is that they cannot be measured directly. One can only measure the battery voltage, which equals EMF+overpotential in charge mode, EMF−overpotential in discharge mode and EMF in equilibrium mode. This means that when the battery voltage is measured and the EMF is known (which is the case in the algorithm of U.S. Pat. No. 6,515,453), one can derive an estimate of the overpotential. A remaining difficulty is the fact that the overpotential depends on many factors, including SoC, current, temperature, time, and age of the battery, as well as spread with regard to other batteries of the same batch. Therefore, an update mechanism should occur when most of these variables are kept constant, because otherwise a change in overpotential can be attributed to too many different factors.

A possible implementation of the overpotential function has been given in U.S. Pat. No. 6,515,453. The general form is repeated here for reference:

η(Q,T,I,t)=ηₒₕₘ(T,I,t)+η_{ct}(T,I,t)+η_{diff}(T,I,t)+η_{q}(q,T,I,t) (1)

The overpotential can be viewed as a sum of the overpotential due to ohmic resistance (ηₒₕₘ), due to charge-transfer resistance (η_{ct}), due to electrolyte diffusion/migration(η_{diff}) and due to solid-state diffusion (η_{q}). These respective terms can be described by (repeated from U.S. Pat. No. 6,515,453):

$$\begin{matrix}{η}_{ohm} ( T , I , t ) = I ( t ) {R}_{ohm} ( T ) & ( 2 ) \\ {η}_{ct} ( T , I , t ) = I ( t ) {R}_{ct} ( T ) [ 1 - exp ( \frac{- t}{{R}_{ct} ( T ) {C}_{dl} ( T )} ) ] & ( 3 ) \\ {η}_{diff} ( T , I , t ) = I ( t ) {R}_{diff} ( T ) [ 1 - exp ( \frac{- t}{{R}_{diff} ( T ) {C}_{diff} ( T )} ) ] & ( 4 ) \\ {η}_{q} ( q , T , I , t ) = I ( t ) {R}_{q} ( T ) [ \frac{1}{{q}_{max} - q} ] & ( 5 )\end{matrix}$$

The variables time (t), temperature (T) and current (I) can be clearly recognized in these equations. Variable q corresponds to the estimated battery SoC in absolute terms. In this case, the parameters that can be updated include Rₒₕₘ, R_{ct}, C_{dl}, R_{diff}, C_{diff} and R_{q}. Paramater qₘₐₓ equals Capₘₐₓ in this ID and is updated in a separate update mechanism described above.

During charging, the current is constant in CC mode, and the temperature can also be considered constant, because in most cases the charger will be used in-house, where temperature variations are limited. Moreover, during normal CC charging the charge current is not interrupted, so after the overpotentials have built up at the initial stages of charging relaxation processes (the time variable) also do not play a dominant role. Therefore, updating parameters in the overpotential functions to deal with battery ageing should be performed during the CC region when charging the Li-ion battery, because overpotential variations can then be attributed to wrong values of the parameters only. Note that this is an advantage of performing the update mechanism during charging in CC mode. This is no restriction, however, because the I, T, and t variables are taken into account in the overpotential function and this dependence can be dealt with in the update mechanism.

The basic method is that the battery voltage is measured in CC mode, which is already implemented by default in all existing Li-ion chargers. In addition to this, the implemented SoC algorithm estimates the SoC based on current measurement and integration (the system operates in the charge state, hence in non-equilibrium), taking the SoC value at the start of charging as starting point and using the latest Capₘₐₓ parameter for a translation from Coulombs to a percentage scale. This SoC in percentage can be used to assess the EMF value using the same EMF curve that is used the other way around (voltage in, SoC out) in equilibrium mode. The overpotential can now be determined for this SoC, current and temperature values by subtracting the determined EMF value from the measured battery voltage value. At the same time, the overpotential can be calculated under the same conditions (SoC, current, temperature), as the system contains an overpotential function to estimate the remaining time of use, as explained above. The estimated overpotential ηₘₑₐₛ derived from the measured battery voltage can now be compared to the calculated overpotential η_{calc}. Note that both have been determined for the same SoC, current and temperature. The difference between ηₘₑₐₛ and η_{calc} can now be used as input for an Adaptive Control Unit (ACU). By changing the parameters in the overpotential function that yields η_{calc} the ACU will now strive to minimize the difference between ηₘₑₐₛ and η_{calc} for subsequent values of SoC. By repeating this process for increasing SoC values during CC mode, the ACU should be able to converge to a new set of parameters of the overpotential function such that the difference between the ‘real’ overpotential ηₘₑₐₛ (derived from measured battery voltage and stored EMF curve) and the calculated overpotential η_{calc} is minimized. Various well-known systems can be used to implement the ACU, which is basically an optimiser.

As a result of the update mechanism, the overpotential function parameters will be updated to take into account any drift in e.g. ohmic resistance of the battery due to ageing. An embodiment of this update mechanism will be shown in the next section.

For both update mechanisms as well as the regular SoC algorithm described in U.S. Pat. No. 6,515,453 it is an advantage to implement the EMF curve by means of a physical equation including temperature as a parameter. By doing this, the temperature dependence of the EMF can be dealt with both in normal operation and for the update mechanisms. A possible implementation of this temperature-dependent EMF function is given below (generalized form adapted from thesis/book). The EMF of the battery is determined by the difference in equilibrium potentials of the positive and negative electrodes, see eq. (6).

$${E}_{bat}^{eq} = {E}_{pos}^{eq} - {E}_{neg}^{eq} \qquad ( 6 )$$

For each of the electrodes, the equilibrium potential is described in various phases, in which different parameter values describe the different shapes of the EMF curve in each phase. Each phase transition occurs at a certain SoC value, which can be translated into a certain mol fraction X_{Li}. Note that the mol fraction is indeed a relative quantity, where X_{Li}=1 when all sites in the electrode have been filled with Li-ions and X_{Li}=0 when all Li-ions have been extracted from the electrode. In the example given, two phases are assumed to describe the behaviour of both the positive and negative electrode. The phase transition at the positive electrode occurs at X_{Li}=0.75 and at 0.25 for the negative electrode. In practice, the mol fraction at which a phase transition occurs and the number of phase transitions depend strongly on the battery type.

Positive electrode:

$${( {E}_{pos}^{eq} )}_{phase 1} = {E}_{pos , 1}^{o} + \frac{RT}{n F} [ ln ( \frac{1 - {x}_{Li}^{pos}}{{x}_{Li}^{pos}} ) - {U}_{pos , 1} {x}_{Li}^{pos} + {ζ}_{pos , 1} ] \qquad ( 7 )$$

### for X_{Li}≧0.75, and

$${( {E}_{pos}^{eq} )}_{phase 2} = {E}_{pos , 2}^{o} + \frac{RT}{n F} [ ln ( \frac{1 - {x}_{Li}^{pos}}{{x}_{Li}^{pos}} ) - {U}_{pos , 2} {x}_{Li}^{pos} + {ζ}_{pos , 2} ] \qquad ( 8 )$$

for x_{Li}<0.75.

Negative electrode:

$${( {E}_{neg}^{eq} )}_{phase 1} = {E}_{neg , 1}^{o} + \frac{RT}{n F} [ ln ( \frac{1 - {x}_{Li}^{neg}}{{x}_{Li}^{neg}} ) - {U}_{neg , 1} {x}_{Li}^{neg} + {ζ}_{neg , 1} ] \qquad ( 9 )$$

### for X_{Li}>0.25, and

$${( {E}_{neg}^{eq} )}_{phase 2} = {E}_{neg , 2}^{o} + \frac{RT}{n F} [ ln ( \frac{1 - {x}_{Li}^{neg}}{{x}_{Li}^{neg}} ) - {U}_{neg , 2} {x}_{Li}^{neg} + {ζ}_{neg , 2} ] \qquad ( 10 )$$

### for X_{Li}≧0.25.

In order to avoid a discontinuity in the curve, the following relation between the U₁, U₂, ζ₁ and ζ₂ parameters are valid, assuming E^{o}₁=E^{o}₂ (x_{phase transition}=0.75 for pos. and 0.25 for neg. electrode):

ζ₂=(U₂−U₁)χ_{phase transition}+ζ₁ (11)

Temperature dependence of the parameters E^{o}, U and ζ can also be taken into account. For E^{o} this temperature dependence is given by:

$${E}^{o} ( T ) = {E}^{o} ( {T}_{ref} ) + ( T - {T}_{ref} ) \frac{Δ S}{n F} \qquad ( 12 )$$

where T_{ref} is the reference temperature, e.g. 298 K.

### DETAILED DESCRIPTION OF HOW TO BUILD AND USE THE INVENTION

The proposed invention should be implemented in an SoC algorithm implemented in a portable device powered by a rechargeable Li-ion battery. In principle, parts of the invention could also be applied in SoC systems for other rechargeable battery types.

The battery voltage, temperature and current are used as inputs to the system. These analog variables are digitized and fed to a micro controller. The SoC algorithm proposed in U.S. Pat. No. 6,515,453 runs on the micro controller, with the addition of the two update mechanisms for Capₘₐₓ and the overpotential function described above. Moreover, both the EMF as the overpotential should be described as a function of temperature and other variables and parameters, as described above. The time reference is obtained from a crystal oscillator. The ROM stores predefined functions and parameters, such as the EMF curve, Capₘₐₓ and the initial set of parameters for the overpotential function. The RAM is used to store updated battery information. Methods to update the EMF curve have been described in U.S. Pat. No. 6,420,851. Embodiments of the Capₘₐₓ and overpotential function update mechanisms will be described below.

### Update Mechanism for Capₘₐₓ

The embodiment for the Capₘₐₓ parameter is given by means of a flow chart below. In addition to the embodiment shown, several supplements can be thought of: When the user does not apply overnight charging, but quickly wants to recharge part of the battery capacity, the update mechanism could be skipped by e.g. a user switch. This prevents unnecessary waiting time at the beginning of charging. Another alternative for this was mentioned above in the form of taking the latest SoC value before entering charge mode as starting value.

The newly determined Capₘₐₓ value could be compared to the old value and the number of charge/discharge cycles since the last update. Unrealistic changes in value could be blocked in some cases and the old value could then be retained.

Although the conditions should be constant, one could place the charger in either a very cold or very hot place. This could influence the accuracy of the method and hence the update mechanism should be skipped in these extreme cases.

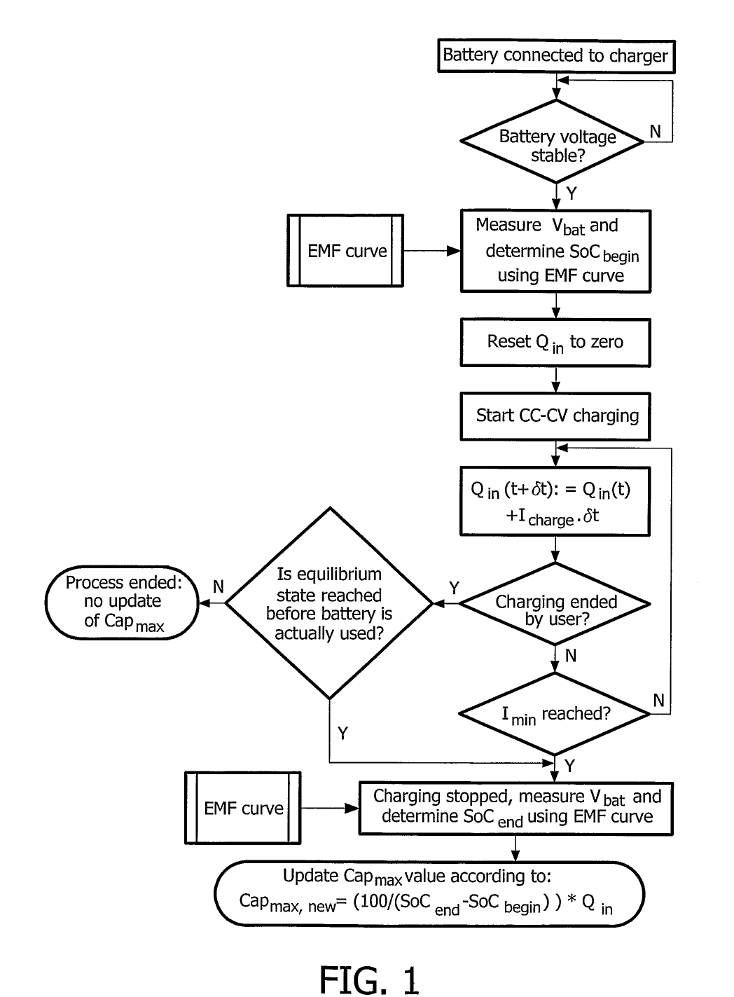

FIG. 1 shows a flow diagram of Capₘₐₓ update mechanism

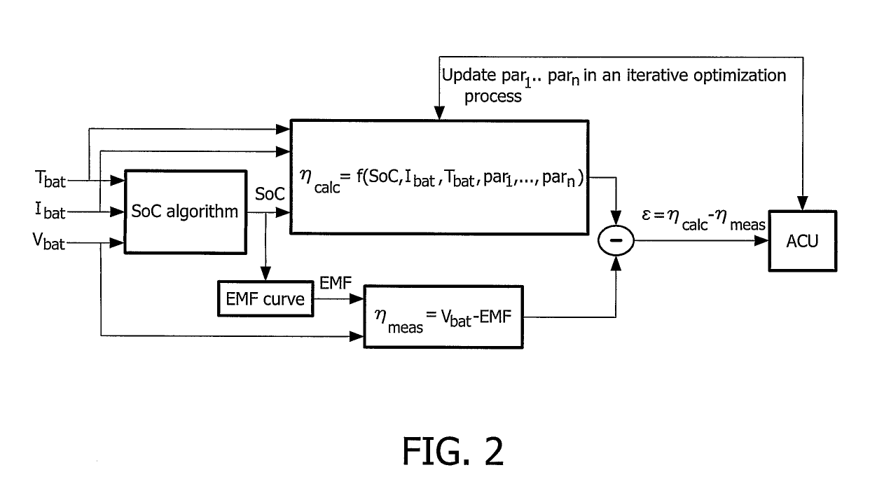

An embodiment of the overpotential function update mechanism is shown in FIG. 2, which shows a preferred embodiment of mechanism to update parameters par₁ . . . parₙ in overpotential function.

The SoC value is determined starting from a starting SoC value when entering charge mode and adding the accumulated charge obtained from integrating the charge current. The latest value of the parameter Capₘₐₓ is used to obtain the SoC value on a percentage scale. Each time a new set of battery variables V_{bat}, I_{bat} and T_{bat} is measured, the SoC algorithm estimates a new SoC value. Based on this SoC value the ‘real’ overpotential ηₘₑₐₛ and the calculated overpotential η_{calc} are determined. The difference ε between the two is fed to an ACU. Based on the new value of the error ε compared to earlier error values the ACU decides to update the parameter set par₁ . . . parₙ of the overpotential function. This process is repeated an arbitrary number of times in CC mode of the charging process of a Li-ion battery. The value of the error ε should be minimized in an iterative process. Any optimisation algorithm can be used in the ACU, of which various examples can be found in the open literature. Note that by implementing the overpotential and EMF functions as described above this set-up will work for any value of V, I and T.

Possible supplements of the embodiments are similar to the ones mentioned for the updating mechanism of Capₘₐₓ. A comparison between new and old parameter values, taking into account the number of charge/discharge cycles since the last update, could lead to blocking the new parameter values due to unrealistic changes. Moreover, the update process could be suspended under extreme circumstances, e.g. charging under extreme temperature conditions (below zero degrees Celsius or at very high temperatures of e.g. 60 degrees Celsius or higher).

Finally, one could also think of a slightly different implementation for storing the overpotential function and adapting it for ageing. As explained above, it is possible to ‘measure’ the overpotential during charging. The obtained overpotential values can be stored in a memory. In CC mode, this yields various overpotential values at a constant current and temperature and variable SoC values. The battery impedance is fairly linear with respect to current for Li-ion batteries and only depends on SoC when the battery is almost empty or almost full. Therefore, the battery impedance for other current values can be extrapolated from the stored overpotential values for one current value. This can even be checked in CV mode, because in that case the current decreases, so the system can actually measure the overpotential for currents lower than the CC current and check it with extrapolated currents. As the SoC increases during charging in CV mode, at some point the measured overpotentials will start to differ from the overpotentials obtained from extrapolating the current. This deviation can then be attributed to the SoC approaching the full state. This dependence should then also be stored in some form of linear or polynomial fitting. Temperature dependence of the overpotential can be taken into account by using an Arrhenius equation:

$$η ( T ) = {η}^{o} exp ( \frac{- {E}_{par}^{a}}{RT} ) \qquad ( 13 )$$

where η(T) is the temperature-dependent overpotential, η^{o} is the pre-exponential factor and E^{a}ₚₐᵣ is the activation energy of the overpotential. For the measured temperature the values of η^{o} and E^{a}ₚₐᵣ could be updated, which updates the complete temperature-dependence of the overpotential. Basically, one stores the dependencies of the overpotential on I, SoC and T in a loop-up table, where some of the table cells are directly filled in with measurements and others are filled in based on extrapolations of measured points, taking some assumed basic (linear, quadratic, etc) dependence into account. As the overpotential is linear and symmetrical, the overpotentials stored for charging current I can also be used for discharging current I.

The invention can be applied in portable battery-powered equipment, particularly for Li-ion batteries. The invention leads to accurate estimation of the battery SoC, even during aging of the battery. Adaptivity of a SoC indication system is crucial.

1. A method of estimating the state-of-charge of a Li-ion battery, comprising the steps of:
measuring the voltage across the battery during a first measurement and converting this measured value into the state-of-charge (SoCₛ);
subsequently charging the battery;
measuring the voltage across the battery during a second measurement and converting this measured value to a measured state-of-charge value(SoCₑ);
determining the accumulated charge during charging by integration of the charge current;
subtracting the measured state of charge (SoCₛ) in the first measurement from the state-of-charge (SoCₑ) in the second measurement; and
updating the value of the maximum capacity of the battery (Capₘₐₓ) by relating the charge withdrawn from the battery with the result of the subtraction (SOCₑ-SOCₛ),
characterized in that at least the second measurement is executed during charging.

2. A method as claimed in claim 1, characterized in that during the second measurement the current has a value at which the battery can be regarded to be in equilibrium.

3. Method as claimed in claim 1, characterized in that the Li-ion battery is charged according to the CC-CV-regime and that the second measurement takes place in the CV-regime.

4. A method as claimed in claim 1, characterized in that the charging takes place by a pulsed current and that the measurements of voltage and current of the battery are subjected to low pass filtering.

5. A method as claimed in claim 1, characterized in that both measurements of the voltage of the battery take place with substantially the same temperature.

6. A method as claimed in claim 1, characterized by the following steps:
measuring the voltage of the battery in equilibrium;
converting the measured voltage to a relative state-of-charge;
integrating of the current in the non-equilibrium state to an accumulated charge;
dividing the accumulated charge by the maximal capacity of the battery;
adding the accumulated relative charge to the a relative state-of-charge obtained earlier in the equilibrium state of the battery.

7. A method as claimed in claim 1 characterized in that the value of the state of charge is used to calculate an estimation of the remaining time of use of the battery.

8. Method as claimed in claim 7, characterized in that in the calculation of the remaining time of use an estimation of the overpotential is used.

9. A method as claimed in claim 8, characterized in that the estimation of the overpotential is determined by a model which regularly updated.

10. Method as claimed in claim 9, characterized in that the updating comprises the following steps:
determining the state of charge of the battery;
charging the battery;
measuring the battery voltage at a moment during charging;
determining the state-of-charge of the battery at the moment of the measurement by integration of the charge current and adding the result to the initial value of the state-of-charge;
determining the value of the EMF from the state-of-charge;
determining the overpotential by subtracting the determined value of the EMF from the measured voltage;
estimating the overpotential through a model wherein the same values for state-of-charge, current and temperature are used; and
adapting the model by comparison with the determined overpotential.

11. Method as claimed in claim 10, characterized in that the method is repeated with another value of any of the following parameters: the state-of-charge, the charge current or the temperature.

12. Method as claimed in claim 10, characterized in that the method is repeated more than once, and that the parameters used in the design are adaptively updated with each measurement.

13. Rechargeable battery, characterized by means for executing a method as claimed in claim 1.

14. Charge apparatus, characterized by means for executing a method as claimed in claim 1.

15. Apparatus, comprising:
measuring means for measuring the voltage across a rechargeble battery;
storage means for storing a relation between the voltage across the battery and the state-of-charge of the battery; and
current measurement means for measuring the charge current of the battery;
integrating means for integrating the charge current;
calculating means for converting this measured value into a state-of-charge value(SoCₛ) by using a relation between the voltage across the battery and the state-of-charge, wherein the calculating means are adapted to subtract the results of two consecutive measurements and to update the value of the maximum capacity of the battery (Capₘₐₓ) by relating the charge supplied to the battery to the result of the subtraction (SoCₑ-SoCₛ),
characterized in that the apparatus is adapted to execute the second measurement during charging.

16. Apparatus as claimed in claim 17, characterized in that a low pass filter is incorporated into the measuring means.

17. Apparatus as claimed in claim 13, characterized in that the apparatus comprises a digital processor.
